(19) United States
(12) Patent Application Publication
(10) Pub. No.: US 2022/0172976 A1
(43) Pub. Date: Jun. 2, 2022

(54) Arrangement and Method for Producing an Arrangement and a Component

(71) Applicant: OSRAM Opto Semiconductors GmbH, Regensburg (DE)

(72) Inventors: Andreas Biebersdorf, Regensburg (DE); Stefan Illek, Donaustauf (DE); Christoph Klemp, Regensburg (DE); Felix Feix, Jena (DE); Ines Pietzonka, Donaustauf (DE); Petrus Sundgren, Lappersdorf (DE); Christian Berger, Marburg (DE); Ana Kanevce, Stuttgart (DE); Karl Engl, Niedergebraching (DE)

(21) Appl. No.: 17/607,804

(22) PCT Filed: Apr. 21, 2020
(86) PCT No.: PCT/EP2020/061079

§ 371 Date: Oct. 29, 2021

(30) Foreign Application Priority Data
Apr. 30, 2019 (DE) 102019111175.7

(51) Int. Cl. H01L 21/683; H01L 25/075

(52) U.S. Cl. CPC H01L 21/6835; H01L 2221/68363; H01L 2221/68354; H01L 25/0753

(57) ABSTRACT

In an embodiment an arrangement includes a plurality of semiconductor chips arranged on a carrier, wherein the carrier is a growth substrate or an auxiliary carrier, wherein the semiconductor chips are arranged at grid points of a grid, and wherein the grid is a hexagonal grid deformed by a deformation factor along at least one of a plurality of axes of the grid and has a shearing along at least one of the plurality of axes of the grid.

This patent application is a national phase filing under section 371 of PCT/EP2020/061079, filed Apr. 21, 2020, which claims the priority of German patent application 10 2019 111 175.7, filed Apr. 30, 2019, each of which is incorporated herein by reference in its entirety.

### TECHNICAL FIELD

An arrangement and a method for producing an arrangement and a component are specified.

### SUMMARY

Embodiments provide an arrangement that can be operated efficiently. Further embodiments provide an efficient method for producing an arrangement.

According to at least one embodiment of the arrangement, the arrangement comprises a plurality of semiconductor chips which are arranged on a carrier. Semiconductor chips can be, in particular, optoelectronic semiconductor chips or electronic semiconductor chips.

The plurality of semiconductor chips can number at least 100 semiconductor chips, at least 1000 semiconductor chips, or at least 100,000 semiconductor chips.

The semiconductor chips can be connected to the carrier. This means that the semiconductor chips can be attached to the carrier. The semiconductor chips are arranged next to one another on the carrier. Preferably, the semiconductor chips are spaced apart from one another on the carrier. This means that the semiconductor chips are not in direct contact with one another. In particular, the carrier may comprise a semiconductor material and/or an electrically insulating material. For example, the carrier may be a growth substrate or an auxiliary carrier.

According to at least one embodiment of the arrangement, the semiconductor chips are arranged at grid points of a grid. This means that one semiconductor chip is arranged at each grid point. The grid is an imaginary grid on a surface of the carrier. The semiconductor chips are arranged on the surface of the carrier at imaginary grid points of this grid. The grid can be distinguished by the fact that the grid points are arranged at equal distances apart from one another in two different directions. Also, the grid can comprise a unit cell. The grid points can be node points of the grid. The grid is a two-dimensional grid. The semiconductor chips can be arranged in such a way that a semiconductor chip is arranged at each grid point. The chip that is arranged at a grid point covers this grid point. For example, a distinctive point of each semiconductor chip covers the associated grid point. For example, the distinctive point is the geometric center of gravity of the semiconductor chip.

According to at least one embodiment of the arrangement, the grid is provided by a hexagonal grid which is deformed by a deformation factor along at least one of the axes of the grid and/or has a shearing along at least one of the axes of the grid. In a hexagonal grid, the closest grid points are separated by a first interval in a first direction. In a second direction, which extends at an angle of 90° to the first direction, the closest grid points are separated by a second interval. The first interval and the second interval are different. In a hexagonal grid the first interval and the second interval are different from each other by a factor of V. The first interval and the second interval can be at least 1 μm and at most 150 μm in each case. One axis of the grid can extend along the first direction. Another axis of the grid can extend along the second direction.

In the event that at least one of the axes of the grid is deformed by a deformation factor, the first interval and the second interval are different from each other by a factor other than V. The second direction extends at an angle of 90° to the first direction. The deformation factor specifies by what factor the ratio between the first interval and the second interval differs from the ratio in a hexagonal grid, that is, the ratio of \sqrt{3}. This means that the deformation factor is given by

$$α = \frac{a}{b \sqrt{3}} ,$$

where α is the deformation factor, a is the first interval and b is the second interval. This means that the grid, at the grid points of which the semiconductor chips are arranged, is given in this case by the fact that the first interval and the second interval are arranged in a ratio of α*\sqrt{3} to each other. Thus, the grid at the grid points of which the semiconductor chips are arranged deviates from the shape of a hexagonal grid by the deformation factor along at least one of the axes of the grid.

If the grid has a shearing along at least one of the axes of the grid, the first direction and the second direction enclose an angle which is different from 90°. The shearing can be described by a shear length. For example, the grid can have a shearing along the first direction. This means that a second grid point, which is the nearest grid point to a first grid point along the second direction, is spaced apart from the first grid point along the first direction by the shear length. The shear length normalized to the interval between two closest grid points along the first direction gives a shear factor of the shearing. Thus:

$$S = \frac{δ}{a} ,$$

where S is the shear factor, δ is the shear length, and a is the interval between two adjacent grid points along the first direction. The shearing therefore means that each grid point along the first direction is spaced apart from the nearest adjacent grid point in the second direction by the shear length. In comparison to the hexagonal grid, the grid points are thus shifted parallel to each other along one of the axes of the grid.

Additionally or alternatively, a shearing along the second direction is also possible.

According to at least one embodiment of the arrangement, the arrangement comprises a plurality of semiconductor chips arranged on a carrier, wherein the semiconductor chips are arranged at grid points of a grid and the grid is provided by a hexagonal grid which is deformed by a deformation factor along at least one of the axes of the grid and/or has a shearing along at least one of the axes of the grid.

The arrangement described here has the advantage that it can be operated efficiently. For producing an arrangement of semiconductor chips for use in a component it is advantageous to arrange semiconductor chips on a carrier at grid points of an at least approximately hexagonal grid. As a result, the density of the semiconductor chips per unit area on the carrier is a maximum, i.e. the costs are low due to the space-saving arrangement of the semiconductor chips. Furthermore, the local environment of each individual semiconductor chip is more homogeneous than, for example, in a Cartesian arrangement. This results in more homogeneous results of the processes required for manufacturing and thus in improved performance and more homogeneous properties of the semiconductor chips. In addition, a degeneration of the semiconductor chips in the operation of these chips can be reduced.

For the semiconductor chips produced in this way to be used in a component for an intended application, the semiconductor chips are transferred from the carrier with a transfer tool. Thus, the semiconductor chips can be mounted in or on the component for the intended application. For example, a plurality of semiconductor chips can be produced on a carrier on which the semiconductor chips are arranged at grid points of a hexagonal grid. These semiconductor chips are mounted with a transfer tool on another carrier, for example, of a display. In this case, the display is the component for the intended application of the semiconductor chips. The semiconductor chips in this case are optoelectronic semiconductor chips.

This method for transferring the semiconductor chips has the disadvantage that the semiconductor chips can only be transferred inefficiently. Typically, the transfer tool has a Cartesian shape, whereas the semiconductor chips are arranged at grid points of a hexagonal grid. Therefore, only one row of semiconductor chips which are arranged next to each other on a straight line along an axis of the grid can be transferred at a time. A Cartesian transfer tool comprises transfer points for attaching one semiconductor chip each, wherein the transfer points are arranged at grid points of a square grid or a rectangular grid.

In the arrangement described here, the semiconductor chips can be arranged on the carrier in such a way that more than one parallel row of semiconductor chips can be transferred simultaneously with a Cartesian transfer tool. At the same time, the arrangement has the advantages of a hexagonal arrangement of the semiconductor chips on the carrier, since the arrangement of the semiconductor chips on the carrier deviates only slightly from a hexagonal arrangement. Thus, the semiconductor chips of the arrangement, and therefore also the component, can be operated efficiently.

In the case in which at least one of the axes of the grid is deformed by a deformation factor, the deformation factor can be chosen in such a way that an integer multiple of the first interval results in an integer multiple of the second interval. Thus, using the Cartesian transfer tool, semiconductor chips can be transferred along the first and along the second direction simultaneously, wherein only the semiconductor chips that are separated from one another by an integer multiple of the respective interval are transferred. This means that the n-fold multiple of the first interval can be equal to the m-fold multiple of the second interval. In this case, every n-th semiconductor chip along the first direction and every m-th semiconductor chip along the second direction can be transferred simultaneously using a Cartesian transfer tool. The numbers n and m are different integers. As a result, the semiconductor chips can be transferred more efficiently overall. Therefore, a component comprising the transferred semiconductor chips can be produced efficiently and the semiconductor chips of the arrangement can be operated efficiently.

In the case in which the grid has a shearing along at least one of the axes of the grid, the shear factor can be chosen in such a way that the semiconductor chips can be transferred with a Cartesian transfer tool. For this purpose, an integer multiple of the first interval can be equal to an interval between two semiconductor chips along a direction perpendicular to the first direction. Thus, one semiconductor chip can be assigned to each transfer point of the transfer tool on the carrier. This means that a plurality of parallel rows of semiconductor chips can be transferred simultaneously with the transfer tool. As a result, a component comprising the transferred semiconductor chips can be produced efficiently and the semiconductor chips of the arrangement can be operated efficiently.

According to at least one embodiment of the arrangement, the semiconductor chips are optoelectronic semiconductor chips. The optoelectronic semiconductor chips are, for example, luminescent diode chips such as light-emitting diode chips or laser diode chips. The semiconductor chips can have an active region. The active region can be designed to emit and/or detect electromagnetic radiation in the operation of the optoelectronic semiconductor chip. The active region can comprise at least one quantum well structure. The use of optoelectronic semiconductor chips makes it advantageously possible to use them in optical applications, for example in a display.

According to at least one embodiment of the arrangement, the deformation of the hexagonal grid by a deformation factor involves compression or stretching. In the case of compression, the interval between two adjacent grid points along at least one of the axes of the grid is reduced compared to the interval between these grid points in a hexagonal grid. In the case of stretching, the interval between two adjacent grid points along at least one of the axes of the grid is increased compared to the interval between these grid points in a hexagonal grid. In both cases, the shape of the grid is similar to a hexagonal grid. This means that the arrangement has at least some of the advantages of a hexagonal arrangement of the semiconductor chips on the carrier, while an efficient transfer with a Cartesian transfer tool is possible at the same time.

According to at least one embodiment of the arrangement, the size of the difference deformation factor−1 is greater than 0.001. This means:

|α−1|>0.001.

In other words, the grid differs from the shape of a hexagonal grid along at least one axis by a factor of at least 0.001. Alternatively, the magnitude of the difference deformation factor−1 is greater than 0.005. This means that the arrangement has at least some of the advantages of a hexagonal arrangement of the semiconductor chips on the carrier and an efficient transfer with a Cartesian transfer tool is possible at the same time.

According to at least one embodiment of the arrangement, the magnitude of the difference deformation factor−1 is less than 0.3. This means:

|α−1|<0.3.

In other words, the grid differs from the shape of a hexagonal grid along at least one axis by a factor of no more than 0.3. This means that the arrangement has at least some of the advantages of a hexagonal arrangement of the semiconductor chips on the carrier and an efficient transfer with a Cartesian transfer tool is possible at the same time.

According to at least one embodiment of the arrangement, the magnitude of the difference deformation factor−1 is less than 0.1. This means:

|α−1|<0.1.

In other words, the grid differs from the shape of a hexagonal grid along at least one axis by a factor of no more than 0.1. This means that the arrangement has at least some of the advantages of a hexagonal arrangement of the semiconductor chips on the carrier, and an efficient transfer with a Cartesian transfer tool is possible at the same time.

According to at least one embodiment of the arrangement, the shearing by a shear factor occurs along at least one of the axes of the grid and the magnitude of the shear factor is less than 0.3. This means:

$$\vert \frac{δ}{a} \vert < 0.3 .$$

Alternatively, the magnitude of the shear factor is less than 0.03. Thus, the shape of the grid differs only slightly from the shape of a hexagonal grid. This means that the arrangement has at least some of the advantages of a hexagonal arrangement of the semiconductor chips on the carrier, while an efficient transfer with a Cartesian transfer tool is possible at the same time.

According to at least one embodiment of the arrangement, a first distance, which is given by an integer multiple of the interval between two semiconductor chips along a first direction, is equal to a second distance, which is given by a different integer multiple of the interval between two semiconductor chips along a second direction. This means that the first distance is given by an integer multiple of the first interval. The second distance is given by an integer multiple of the second interval. Thus:

c=n*a

d=m*b

and:

c=d,

where c is the first distance, d is the second distance, and n and m are different integers. This means that in the first direction, a semiconductor chip is arranged at each of the positions of integer multiples of the first distance. In the second direction, one semiconductor chip is arranged at each of the positions of integer multiples of the second distance. As a result, semiconductor chips are arranged at equal intervals along the first direction and along the second direction. These can advantageously be transferred simultaneously using a Cartesian transfer tool.

According to at least one embodiment of the arrangement, the first direction and the second direction are perpendicular to each other. This makes it advantageous to use a Cartesian transfer tool to transfer the semiconductor chips.

According to at least one embodiment of the arrangement, the number of semiconductor chips arranged within the first distance along the first direction is different from the number of semiconductor chips arranged within the second distance along the second direction. This means that the interval between two adjacent semiconductor chips along the first direction is different from the interval between two adjacent semiconductor chips along the second direction. Thus, the grid advantageously deviates only slightly from the shape of a hexagonal grid.

Furthermore, a method for producing an arrangement is specified. The arrangement can preferably be produced using a method described here. In other words, all the features disclosed for the arrangement are also disclosed for the method for producing an arrangement and vice versa.

According to at least one embodiment of the method for producing an arrangement, the method comprises a method step in which a plurality of semiconductor chips is provided. The semiconductor chips can be manufactured separately from each other or on a common carrier.

According to at least one embodiment of the method for producing an arrangement, the method comprises a method step in which the semiconductor chips are arranged on a carrier at grid points of a grid. The semiconductor chips can be produced on the carrier. This means that the semiconductor chips are produced in such a way that they are arranged on the carrier at the grid points of the grid. Alternatively, it is possible for the semiconductor chips not to be produced on the carrier and to be mounted on it after production. In this case, the semiconductor chips are arranged on the carrier at grid points.

According to at least one embodiment of the method for producing an arrangement, the grid is provided by a hexagonal grid which is deformed along at least one of the axes of the grid by a deformation factor and/or has a shearing along at least one of the axes of the grid.

The semiconductor chips are thus arranged on the carrier in such a way that the arrangement has at least some of the advantages of a hexagonal arrangement of the semiconductor chips, since the grid differs only slightly from the shape of a hexagonal grid. In addition, the arrangement can be efficiently produced, since the grid can be chosen in such a way that a plurality of semiconductor chips can be transferred simultaneously with a Cartesian transfer tool.

A method for producing a component is also specified. According to at least one embodiment of the method for producing a component, an arrangement is produced according to a method described here. Thereafter, some of the semiconductor chips are transferred from the carrier to another carrier simultaneously using a transfer tool, wherein the semiconductor chips which are simultaneously transferred are arranged at grid points of an orthogonal grid. This may mean that semiconductor chips at positions of a specific integer multiple of the first interval along the first direction are transferred simultaneously with semiconductor chips at positions of a specific integer multiple of the second interval along the second direction. For example, each n-th semiconductor chip along the first direction and each m-th semiconductor chip along the second direction are simultaneously transferred, where n and m are integers. In this case, the first distance and the second distance can be equal. This means that the semiconductor chips that are transferred simultaneously are arranged at grid points of a square grid. Furthermore, it is possible for the first distance to be different from the second distance. In this case, the semiconductor chips that are transferred simultaneously are arranged at grid points of an orthogonal grid, namely a rectangular grid. As a result, the semiconductor chips can be efficiently transferred using a Cartesian transfer tool.

According to at least one embodiment of the method for producing a component, the carrier is rotated relative to the transfer tool by a predetermined angle before the transfer. The carrier can be rotated in such a way that after the rotation, some of the semiconductor chips are arranged at grid points of an orthogonal grid. These semiconductor chips can each be assigned to a transfer point of the transfer tool. This means that a plurality of semiconductor chips can be transferred simultaneously using a Cartesian transfer tool.

The carrier can be rotated in such a way that semiconductor chips can be spaced apart from each other along a third direction by a third distance. In addition, semiconductor chips are spaced apart from each other along a fourth direction by a fourth distance. The third and fourth directions enclose an angle of 90° to each other. Furthermore, the third and fourth directions are each different from the first and second directions. The third and fourth distance can be equal. Thus, semiconductor chips that are arranged along the third direction at positions of integer multiples of the third distance and semiconductor chips that are arranged along the fourth direction at positions of integer multiples of the fourth distance can be transferred simultaneously. As a result, the component can be produced efficiently using a Cartesian transfer tool.

### BRIEF DESCRIPTION OF THE DRAWINGS

In the following, the arrangement described here, the method described here for producing an arrangement and the method described here for producing a component are explained in more detail in conjunction with exemplary embodiments and the associated figures.

FIG. 1 shows a plan view of an arrangement according to one exemplary embodiment; and

FIGS. 2 and 3 each shows a plan view of an arrangement according to further exemplary embodiments.

In conjunction with FIG. 4, an exemplary embodiment of the method for producing an arrangement is described.

### DETAILED DESCRIPTION OF ILLUSTRATIVE EMBODIMENTS

Identical, similar or equivalently functioning elements are labelled with the same reference signs in the figures. The figures and the relative proportions of the elements represented in the figures are not to be considered to be true to scale. Instead, individual elements may be shown exaggerated in size for ease of visualization and/or better understanding.

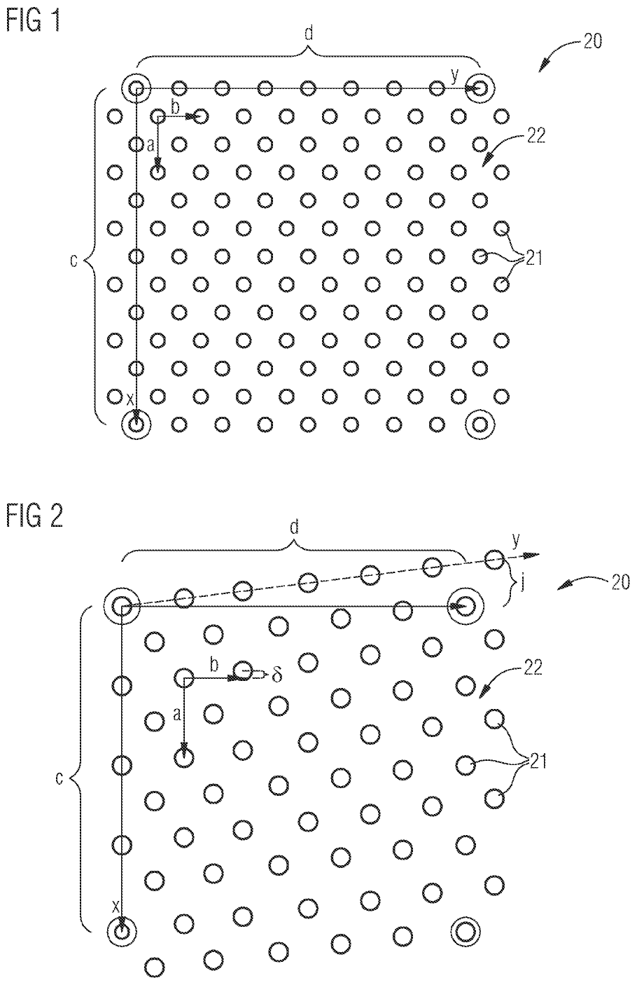

FIG. 1 shows a plan view of an arrangement 20 according to one exemplary embodiment. The arrangement 20 comprises a plurality of optoelectronic semiconductor chips 21 which are arranged on a carrier 22. The semiconductor chips 21 can also have a different shape than the round one shown. The semiconductor chips 21 are arranged at grid points of a grid. The grid is provided by a hexagonal grid, which is deformed by a deformation factor α along one of the axes of the grid.

Along a first direction x, the semiconductor chips 21 are arranged on the carrier 22 at equal intervals from one another. The interval between two adjacent semiconductor chips 21 in the first direction x is a first interval a. Along a second direction y, the semiconductor chips 21 are arranged on the carrier 22 at equal intervals from one another. The interval between two adjacent semiconductor chips 21 in the second direction y is a second interval b. The grid is not a hexagonal grid, because the first interval a and the second interval b are in the following relationship:

$$α = \frac{a}{b \sqrt{3}} ,$$

where α is not equal to 1. The grid is thus compressed or stretched along at least one of the axes of the grid compared to a hexagonal grid.

In addition, the following applies to the first interval a and the second interval b in the exemplary embodiment in FIG. 1:

c=n*a

d=m*b

and:

c=d,

where c is the first distance, d is the second distance, n=6 and m=8. Thus, the first distance c is equal to the second distance d. The first direction x and the second direction y extend perpendicular to each other.

In this exemplary embodiment, the semiconductor chips 21, which are arranged at the grid points shown circled, are arranged at equal distances from each other in the first direction x and in the second direction y. This means that these semiconductor chips 21 are arranged at grid points of an orthogonal grid, namely a square grid. All semiconductor chips 21 which are arranged at grid points of this orthogonal grid can be transferred simultaneously with a Cartesian transfer tool. Thus, a component 23, into or onto which the semiconductor chips 21 are transferred with the Cartesian transfer tool, can be efficiently produced. In addition, this component can be operated efficiently since the semiconductor chips 21 can be operated efficiently.

For this exemplary embodiment the following applies:

0.001<|α−1|<0.3.

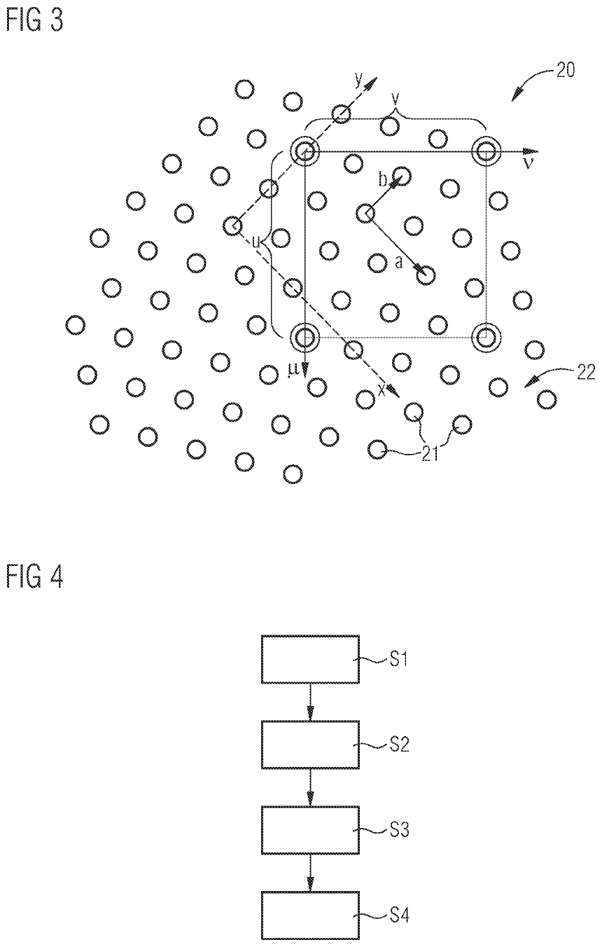

FIG. 2 shows a plan view of a further exemplary embodiment of the arrangement 20. In contrast to the exemplary embodiment shown in FIG. 1, the grid has a shearing along one of the axes of the grid. The first direction x is not perpendicular to the second direction y, wherein the second direction y is represented by a dashed arrow. Thus, two semiconductor chips 21 closest together in the second direction y are located a shear length S away from each other along the first direction x. The grid points of the grid are shifted parallel to each other along the first direction x.

For the first distance c, the following also applies:

c=m*a.

In this case, m=4.

For the second distance d:

$$d = \frac{n * b}{2} ,$$

where n=11. In addition, c=d.

The following applies to the shear factor S:

$$S = \frac{δ}{a} , \\ and$$

$$\vert \frac{δ}{a} \vert = \vert \frac{j}{n} \vert < 0.03 ,$$

where j is the number of half periods along the first direction x, where half a period along the first direction x is equal to half of the first interval a. Furthermore, it is possible that

$$\vert \frac{δ}{a} \vert = \vert \frac{j}{n} \vert < 0.3 .$$

In this exemplary embodiment also, the semiconductor chips 21, which are separated along the first direction x by the first distance c, and the semiconductor chips 21, which are separated along the second direction y by the second distance d, can be transferred simultaneously using a transfer tool. Therefore, using a Cartesian transfer tool the semiconductor chips 21 that are shown circled in FIG. 2 can be transferred simultaneously. In addition, a component 23 which comprises the semiconductor chips 21 can be operated efficiently, since the semiconductor chips 21 can be operated efficiently.

FIG. 3 shows a plan view of a further exemplary embodiment of the arrangement 20. The arrangement 20 has the structure shown in FIG. 1. In addition, the carrier 22 is rotated by a predetermined angle. Thus, the carrier 22 is rotated relative to the transfer tool by the predetermined angle before transferring some of the semiconductor chips 21. Along a third direction p, two semiconductor chips 21 are each separated from each other by a third distance u. Along a fourth direction v, two semiconductor chips 21 are each separated by a fourth distance v. The third distance u is equal to the fourth distance v. The third direction p and the fourth direction v are each different from the first direction x and the second direction y. This means that the semiconductor chips 21, which are shown circled in FIG. 3, are arranged at grid points of an orthogonal grid. Thus, these semiconductor chips 21 can be transferred simultaneously with a Cartesian transfer tool.

In addition, in this exemplary embodiment the following relation applies to the first interval a and the second interval b:

5b=3a

and therefore:

α=0.96.

The grid is thus stretched along the second direction y by 4% relative to a hexagonal grid.

In conjunction with FIG. 4, an exemplary embodiment of the method for producing an arrangement 20 is described. In addition, an exemplary embodiment of the method for producing a component 23 is described. The steps of the method can be carried out in the specified order. In a first step S1 of the method for producing an arrangement 20, a plurality of semiconductor chips 21 is provided.

In a second step S2, to produce the arrangement 20 the semiconductor chips 21 are arranged on the carrier 22 at grid points of a grid. The grid is provided by a hexagonal grid, which is deformed by a deformation factor α along at least one of the axes of the grid and/or has a shearing along at least one of the axes of the grid.

This is followed by an optional third step S3 for producing the component 23. This involves rotating the carrier 22 by a predetermined angle relative to a transfer tool.

In a fourth step S4, according to the exemplary embodiment of the method for producing the component 23 some of the semiconductor chips 21 are transferred simultaneously from the carrier 22 to another carrier using the transfer tool, wherein the semiconductor chips 21 that are transferred simultaneously are arranged at grid points of an orthogonal grid. All transfer points of the transfer tool can be used, or else only some of the transfer points, for example every second one, are used. The semiconductor chips 21 can be transferred with the transfer tool, for example, using adhesive stamps of the transfer tool or electrostatic forces.

The additional carrier can be a part of the component 23, which is a display module, for example. When a Cartesian transfer tool is used, the semiconductor chips 21 can be transferred efficiently. The grid, at the grid points of which the semiconductor chips 21 are arranged on the carrier 22 of the arrangement 20, is chosen in such a way that semiconductor chips 21 which are arranged along two different directions can be transferred simultaneously using the transfer tool. It is also possible to adapt the grid to the intervals at which the semiconductor chips 21 are required on the additional carrier.

The invention is not limited to the embodiments by the fact that the description is based on them. Rather, the invention comprises each new feature, as well as any combination of features, which includes in particular every combination of features in the patent claims, even if this feature or this combination itself is not explicitly specified in the patent claims or exemplary embodiments.

1.-13. (canceled)

14. An arrangement comprising:
a plurality of semiconductor chips arranged on a carrier,
wherein the carrier is a growth substrate or an auxiliary carrier,
wherein the semiconductor chips are arranged at grid points of a grid, and
wherein the grid is a hexagonal grid deformed by a deformation factor along at least one of a plurality of axes of the grid and has a shearing along at least one of the plurality of axes of the grid.

15. The arrangement as claimed in claim 14, wherein the semiconductor chips are optoelectronic semiconductor chips.

16. The arrangement as claimed in claim 14, wherein the deformation of the hexagonal grid by the deformation factor involves compression or stretching.

17. The arrangement as claimed in claim 14, wherein a magnitude of a difference deformation factor−1 is greater than 0.001.

18. The arrangement as claimed in claim 14, wherein a magnitude of a difference deformation factor−1 is less than 0.3.

19. The arrangement as claimed in claim 14, wherein a magnitude of a difference deformation factor−1 is less than 0.1.

20. The arrangement as claimed in claim 14, wherein the shearing by a shear factor occurs along at least one of the plurality of axes of the grid, and wherein a magnitude of the shear factor is less than 0.3.

21. The arrangement as claimed in claim 14, wherein a first distance, which is given by an integer multiple of an interval between two semiconductor chips along a first direction, is equal to a second distance, which is given by a different integer multiple of an interval between two semiconductor chips along a second direction.

22. The arrangement as claimed in claim 21, wherein the first direction and the second direction are perpendicular to each other.

23. The arrangement as claimed in claim 21, wherein a number of semiconductor chips arranged within the first distance along the first direction is different from a number of semiconductor chips arranged within the second distance along the second direction.

24. A method for producing an arrangement, the method comprising:
providing a plurality of semiconductor chips;
arranging the semiconductor chips on a carrier at grid points of a grid; and
simultaneously transferring some of the semiconductor chips from the carrier to another carrier using a transfer tool,
wherein the carrier is a growth substrate or an auxiliary carrier,
wherein the grid is a hexagonal grid deformed by a deformation factor along at least one of a plurality of axes of the grid and/or has a shearing along at least one of the plurality of axes of the grid, and
wherein the semiconductor chips that are transferred simultaneously are arranged at grid points of an orthogonal grid.

25. The method as claimed in claim 24, further comprising rotating, the carrier, by a predetermined angle relative to the transfer tool before a transfer.
